(19) United States
(12) Patent Application Publication
(10) Pub. No.: US 2015/0129030 A1
(43) Pub. Date: May 14, 2015

(54) DIELECTRIC-PASSIVATED METAL INSULATOR PHOTOVOLTAIC SOLAR CELLS

(71) Applicant: Solexel, Inc., Milpitas, CA (US)

(72) Inventors: Pawan Kapur, Burlingame, CA (US); Heather Deshazer, Palo Alto, CA (US); Mohammed Islam, Milpitas, CA (US); Mehrdad M. Moslehi, Los Altos, CA (US)

(21) Appl. No.: 14/538,760

(22) Filed: Nov. 11, 2014

Related U.S. Application Data
(60) Provisional application No. 61/902,526, filed on Nov. 11, 2013.

(51) Int. Cl. H01L 31/0224; H01L 31/18

(52) U.S. Cl. CPC H01L 31/022425; H01L 31/1804
USPC 136/256; 438/98

(57) ABSTRACT

A photovoltaic solar cell is described that, according to one example embodiment, includes a semiconductor light absorbing layer and a dielectric stack on at least one of a front side of the light absorbing layer or a back side of the light absorbing layer. The dielectric stack includes a tunneling dielectric layer being sufficiently thin for charge carriers to tunnel across, and an overlaying dielectric layer being a different material than the overlaying dielectric. The solar cell also includes an electrically conductive contact physically contacting the overlaying dielectric. The electrically conductive contact and the overlaying dielectric together have either a work function suitable for selective collection of electrons that closely matches a conduction band of the light absorbing layer, or a work function suitable for selective collection of holes that closely matches a valence band of the light absorbing layer.

### CROSS REFERENCE TO RELATED APPLICATIONS

This application claims the benefit of U.S. Provisional Application No. 61/902,526, filed Nov. 11, 2013, which is incorporated by reference in its entirety.

### BACKGROUND

1. Field of Art

This description generally relates to solar cells, and particularly to dielectric layers in solar cells.

2. Description of the Related Art

Often, in existing solar cells charge carriers are separated (separation of photogenerated electrons and holes) and extracted from a semiconductor light absorbing layer by placing ohmic metal contacts in physical contact with heavily doped (e.g., about 2×10¹⁹ to 5×10²⁰ dopant atoms/cm³) regions of the semiconductor (for base and emitter connections). The relatively heavily doped regions may serve two purposes. They are meant to be a reflector for the unwanted carrier type and they serve to reduce the electrical contact resistance for the selected carrier type, which may otherwise (without the heavily doped regions for ohmic metal contacts) will form high resistance Schottky contacts due to metal being directly in contact with a lightly doped semiconductor. However, in some instances the heavy doping is not a perfect reflector of the unwanted carriers and may cause some amount of recombination, quantified in terms of surface recombination velocity (SRV), resulting in some loss of efficiency of the solar cell. While the shape and placement of the contact and the doping may be optimized, it may be highly challenging to fully mitigate the recombination caused using this type of metal contact structure.

One existing solar cell includes a relatively lightly doped silicon layer which serves to absorb sunlight. It may be textured on the front side to trap sunlight more efficiently. It may consist of a passivation and an antireflection dielectric layer, which in one instance can be either a silicon nitride layer or a combination of silicon dioxide and silicon nitride layers. Under the front passivation, the silicon layer is doped in a thin layer with a dopant which is opposite dopant polarity to the rest of the dopant to form an emitter. In addition, on the front side, this dielectric layer may be patterned at some interval to access silicon and make contact to it. In the contact openings, silicon is typically heavily doped and a metal overlayer such as silver is deposited. The backside of the absorber layer, in one instance, may be a passivating dielectric which is also interrupted at some intervals or islands and patterned to make contacts. The doping in the back contacts (base contact) will be dissimilar in polarity to the doping polarity in the front of the cell (emitter contact) and the overlying metal may also be dissimilar such as Aluminum instead of Silver. Another existing solar cell structure (typically made as bifacial solar cell) provides passivation (and thus reduced recombination) on the front and the back of the cell using an intrinsic (native, no extra doping) amorphous silicon (a-Si) light absorbing layer. A p+ doped a-Si emitter contact and a layer of Indium Tin Oxide (ITO), which is a transparent conductive oxide, are deposited on the front side, and a n+ doped a-Si base contact followed by a layer of ITO are deposited on the back side. Although the device may be highly efficient, it has several disadvantages, including relative complexity and manufacturing cost. First, a-Si strongly absorbs light, thus this passivation layer must be kept very thin, typically less than 10-15 nm. However, this is in conflict with the requirement of a certain minimum a-Si thickness to achieve good passivation, ending up in a some loss in Jsc due to absorption in a-Si. A second disadvantage is that the even the doped a-Si is electrically not very conductive (particularly the lateral sheet conductance is extremely poor). As a result, in some instances, another electrically conductive material must be deposited to achieve sufficient lateral conduction of charge carriers. Often, these layers, ITO being one example, are expensive and the tools used to deposit them (e.g., plasma sputtering) are expensive manufacturing tools. Adding to the cost, fabricating this solar cell may require a number of expensive process steps, including a combination of plasma-enhanced chemical-vapor deposition (PECVD) and physical-vapor deposition (PVD) processes, that further drive up the cost-per-watt of the solar cell.

### BRIEF DESCRIPTION OF DRAWINGS

FIG. 1 shows an outline of a front contact solar cell according to one embodiment.

FIG. 2A shows a front contact solar cell according to one embodiment.

FIG. 2B shows a bifacial front contact solar cell according to one embodiment.

FIG. 3A shows a semiconductor energy band diagram of a front contact solar cell, according to one embodiment.

FIG. 3B shows a semiconductor energy band diagram of a front contact solar cell at zero applied voltage, according to one embodiment.

FIG. 4 illustrates surface recombination velocity (SRV) as a function of aluminum oxide (Al₂O₃) thickness according to one embodiment.

FIG. 5 illustrates a basic process for fabricating a front contact solar cell starting with a wafer, according to one embodiment.

FIG. 6 illustrates a process for fabricating a front contact solar cell starting with an epitaxial growth process, according to one embodiment.

FIG. 7 illustrates a solar cell including a dielectric backplane sheet, according to one embodiment.

The figures depict embodiments of the present invention for purposes of illustration only. One skilled in the art will readily recognize from the following discussion that alternative embodiments of the structures and methods illustrated herein may be employed without departing from the principles of the invention described herein.

### DETAILED DESCRIPTION

### I. Solar Cell Overview and Benefits

Often, conventional and widely used solar cells use emitter structure to draw holes to p-type polarity and base structure electrons to n-type polarity. The “emitter structures” and the “base structures” may be composite structures which are accomplished using a series of processing steps which entail manufacturing higher doping areas, patterning, and achieving differential dopings—a complex fabrication process. In addition to the complexity, these generic structures may not be the best electrical performers for several reasons. First, the dopings under the contacts which may primarily serve the function of reducing contact resistance of majority carriers and increasing the contact rejection of the minority carriers may entail significant minority carrier loss because of its relative inefficiency at rejection. Second, these structures require raising the temperature of the wafer which in turn, has the risk of compromising the bulk lifetime of the wafer. Thus, a disadvantage of this widely used carrier separation and collection approach is that it is complex, requires several process steps, and does not necessarily render the highest performance.

The structures and methods detailed herein provide solutions may achieve carrier separation with great electrical efficiency and less process complexity. The goal of drawing holes to one external polarity while rejecting electrons at this polarity and drawing electrons to the other polarity while rejecting holes at this polarity may be achieved using deposited dielectrics and or semi-insulating material and metal layers with appropriate and suitable electrical properties. Their electrical properties serve to create the driving force for electrons and holes to go to their preferred external terminals. Electrical properties may also be chosen to ensure that there is an efficient and non-recombining rejection of the undesired carrier type at each terminal.

And while the embodiment detailed herein discusses replacing both the emitter and the base structure of a conventional front contact solar cell with the suggested dielectric/metal structure, the innovations provided herein should not be considered limited to these material/structures sets and it does not preclude the possibility of other class of structures and materials in accordance with the disclosed subject matter, for example:

When either only emitter or only the base structure is replaced while the other polarity is maintained to be similar to the prevalent conventional structures, henceforth a “hybrid” structure. For example, the emitter structure is a conventional cell structure, while the base on the back of a front contact solar cell is replaced by a dielectric/metal combination which allows electrons (N-type substrate) to reach the base contact in the back with high efficiency through the dielectric. In these structures, the Voc may not be necessarily dictated by the difference in the metal workfunctions, which is the driving force when both base and emitter structure are replaced by dielectric, semi-insulating/metal structures.

When the solar cell is a back contact solar cells and both emitter and base are on the back of the solar cell. Here, an advantageous embodiment is to have a common dielectric which is continually shared between the base and emitter while the different patterned metal forms the driving force for carrier separation and a high Voc. However, in an alternative embodiment using different dielectrics for base and emitter along with different metals is not excluded.

The dielectric metal system may be structured and selected according to their electrical properties such as bandgaps and workfunctions in general (guidelines and parameters described in detail herein). Further, the dielectric system itself, and in some instances the metal layer itself, may be a single or multiple layer structure. Two specific examples of the dielectric stacks and metals, which are described herein are:

Al2O3/TiOx with Al or Titanium metal (Base for an n-type substrate) for electron selection and hole rejection, and Al2O3/NiOx with Ni metal for hole selection and electron rejection (Emitter).

SiO2 (<1.5 nm)/a-Si with Aluminum for electron selection/hole rejection, and Al2O3/a-Si with Aluminum for hole selection/electron rejection (emitter for n-type substrate).

A solar cell is described which uses layers of passivation dielectric (referred to as dielectric stacks) and/or semi-insulators located between the front and/or back side of the light absorbing semiconductor layer and the base and/or emitter contacts that conduct current generated by incoming light away from the solar cell. In one embodiment, the base and the emitter contacts are dissimilar metals (or other conductive materials) having different work functions. The light absorbing layer is either an intrinsic (no intentionally introduced external doping) material such as intrinsic crystalline silicon, or has some relatively light doping (e.g., on the order of 1×10¹⁴ to 1×10¹⁵ dopant atoms/cm³)) The V_{OC} of the device is a function of the difference between the work functions of the base and emitter contact metal. Methods for the manufacture of the solar cell are also described.

Within the aforementioned embodiment, there are a number of different possible embodiments. For example, the solar cell may be implemented as a front contact solar cell or a back contact solar cell (i.e., both the base and emitter contacts on the backside, opposite the light-receiving frontside). To fabricate the solar cell, the light absorbing layer may use a wafer of a semiconductor (such as CZ silicon) as a starting point, or it may be epitaxially grown (such as epitaxial silicon). The dielectrics used for the dielectrics stacks may vary, provided they result in the features introduced above and further below. Examples of dielectrics used may include, but are not limited to Al₂O₃, SiO₂, TiOₓ, and NiOx (where amount of Oxygen x may vary for both TiOₓ and NiOₓ). Examples of metals used for the contacts may include, but are not limited to Al, Ti, Al/Ti, Ni, and Pt, as well as various alloys thereof.

The solar cell innovations provided herein may also dramatically reduce the number of process steps needed to fabricate a high efficiency solar cell—thus resulting in reduced manufacturing cost while providing relatively high conversion efficiencies. The steps being eliminated may include steps required to create a dopant source layer, a high temperature anneal step to drive the dopant in, and steps related to patterning the passivation to create a contact. Thus, the solar cell may be generated in few manufacturing steps, for example as described herein This allows for the production of a solar cell that may cost approximately 5-10 cents per watt to make (excluding the cost of starting semiconductor wafer, with the current crystalline silicon solar cell conversion process cost being approximately 15 cents per watt). The process described herein may also fabricate solar cells with comparatively less expensive equipment relative to existing processes. For example the manufacturing tools that may be omitted are high temperature furnaces, the patterning equipment such as lithography (or screen printing) and etching, screen printing or laser ablation patterning This may reduce the amount of manufacturing equipment and facilities capital expenditure needed to create a facility for fabricating a solar cell made according to this process. As the current solar cell market is heavily capital constrained, this represents a dramatic breakthrough.

The solar cell may also be higher efficiency (e.g., in the range of over 20% up to about 26% or even higher for single junction solar cells depending on the semiconductor material) because the minority carrier lifetime of the wafers is kept to its pristine high value owing to the omission of high temperature steps. As introduced above, the process for making the solar cell does necessarily include any high temperature heating steps. As higher temperature processing steps may degrade the quality and minority carrier lifetime of the light absorbing semiconductor layer (e.g., Si) owing to phenomena such as oxygen precipitation and driving of surface impurities—both these factors may reduce the bulk lifetime of the silicon absorber, Heating steps generally represent a necessary compromise in achieving desirable solar cell efficiency. Specifically, heating steps allow the attachment of other layers to the light absorbing layer that perform various functions, such as for establishing strong electrical connections for removing separated charge carriers (holes and electrons) from the semiconductor absorber. However, as the novel processes and structures described do not necessarily include any high temperature steps, this tradeoff is not necessary and thus solar cell minority carrier lifetime is extended and intrinsic semiconductor lifetime along with high efficiency of the light absorbing layer is maintained.

The manner in which the solar cell operates may also increase the efficiency and lifetime of the solar cell. For example, in a front contact embodiment where base and emitter contacts are located on either side of the light absorbing layer, during operation an electric field is established across the light absorbing layer due to doping of the absorber semiconductor substrate.

The solar cell is also able to realize higher open-circuit voltage or V_{OC} compared to existing conventional solar cells. In existing conventional solar cells, the maximum V_{OC} may be restricted by the difference in the work function of differentially doped bulk semiconductors. Because of the tradeoff of losing minority carrier lifetime (MCL) with increasing doping, the base material is kept at moderate to low doping (e.g., about 5×10¹⁴ to 1×10¹⁶ dopant atoms/cm³). This results in the maximum V_{OC} being less than the silicon bandgap difference, which is typically in the range of 0.8 electron volts (eV) instead of 1.12 eV.

### II. Front Contact Solar Cell

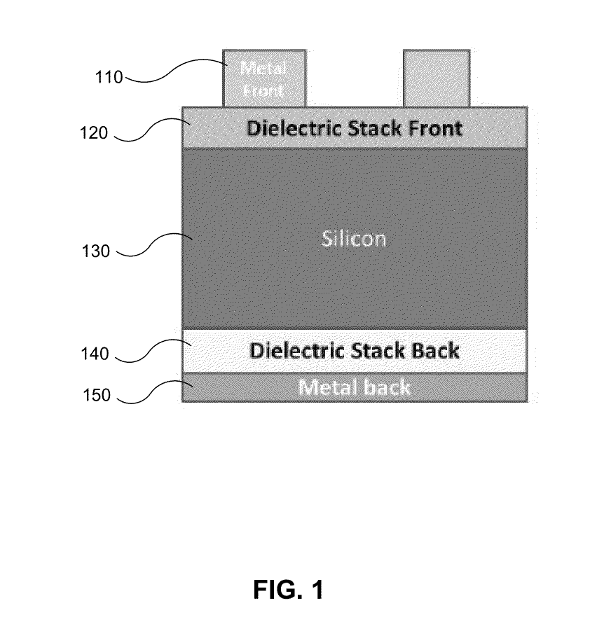

FIG. 1 shows an outline of a front contact solar cell according to one embodiment. The solar cell illustrated in FIG. 1 is a front to back solar cell. The light absorbing semiconductor layer 130, illustrated here as a crystalline silicon (Si) substrate, has either comparatively little doping (e.g., <1×10¹⁵ dopant atoms/cm³) or no additional doping (e.g., it is an intrinsic type semiconductor without intentional extrinsic doping).

The light absorbing semiconductor layer has front side layers (or films) of dielectrics 120 covering the front surface, and back side layers covering of dielectrics 140 covering the back surface. Collectively, the front side layers are referred to as the front dielectric stack 120 (or dielectric stack front), and the back side layers are referred to as the back dielectric stack 140 (or dielectric stack back).

The front dielectric stack 120 effectively passivates the front side of the semiconductor layer, and has either a conduction band or valence band with low resistance (providing charge carrier selectivity) to a front contact 110 (Metal front). The front dielectric stack in one embodiment includes at least two dielectric layers (not shown in FIG. 1): a tunneling dielectric layer physically contacting the front side of the light absorbing layer, and an overlaying dielectric layer physically contacting the front contact metal. The front dielectric stack may also include one or more intervening dielectric layers between those two layers.

The back dielectric stack 140 passivates the back side and has either a valence band or conduction band (the reverse of the front dielectric stack 120) with low resistance to a back contact 150 (Metal back), hence providing carrier collection selectivity. In one embodiment, the back dielectric includes at least two dielectric layers (not shown in FIG. 1), a tunneling dielectric layer physically contacting the back side of the light absorbing layer, and an overlaying dielectric layer physically contacting the back contact metal. The back dielectric stack may also include one or more intervening dielectric layers between those two layers.

The front 120 and back 140 dielectric stacks are electron and hole receptive (or electron and hole selective), respectively (or the reverse).

Front 110 and back 150 conductive contacts are placed on the front 120 and back 140 dielectric stacks, respectively. In the example of FIG. 1, the front contact 110 is patterned and the back contact 150 is blanketed (covering at least a majority of the surface of the back dielectric stack 140), however the back contact 150 may instead be patterned.

The specific structure of the front 120 and back 140 dielectrics, and the materials used to make the front 110 and back 150 contacts may vary by implementation. The following subsections set forth parameters for creating a high efficiency solar cells, as well as a specific example that addresses each of these parameters.

The following parameters are provided as descriptive guidelines for structure, material, and fabrication selections in accordance with innovative aspects of disclosed subject matter. These parameters may be used in sum, partially, or in combination with other solar cell considerations depending on the characteristics of the solar cell desired.

II.A. Front Dielectric Stack Parameters

1) Passivation: The layers of the front dielectric stack need to provide excellent passivation. In one embodiment, a front dielectric stack having a sufficient passivation has for example, an SRV of lower than 20 cm/s (corresponding to a high-quality surface passivation resulting in very low recombination losses).

2) Contact resistance: In one embodiment, the front dielectric stack has low contact resistance to electrons (carrier selectivity to electrons). This specific contact resistance value may range from approximately 1 mohm-cm² to about 100 mohm-cm², with lower specific contact resistivity values being preferred for higher solar cell efficiencies.

3) Hole Rejection: The front overlaying dielectric is a barrier that selectively rejects holes (positive charges from valence band). In this configuration the solar cell produces power if electron (negative charges from conduction band) accepting front dielectric stack has a negative bias compared to the back which allows holes but rejects electrons.

Importantly, in an alternative embodiment the passivation stacks may be reversed, where the front dielectric stack allows holes and rejects electrons and the back dielectric stack allows electrons and efficiently rejects holes. However, in this scenario, the bias of the cell needs to be reversed such that the front has a positive bias and the back has a negative bias.

4) Low barrier height between the conduction band of the overlaying dielectric and the conduction band of the light absorbing layer: This ensures electrons may easily be transported from the light absorbing layer, through the dielectric, and into the overlaying dielectric. Further, the front dielectric stack materials (and their respective thicknesses) and front contact together yield a work function for electrons that is close to the conduction band of Si. This allows the front side of the solar cell to have a large V_{OC} and also allows for a good contact resistance. The high barrier to the holes along with good passivation quality allows holes to be efficiently rejected from the front surface.

5) Transparency: The materials of the front dielectric stack may be highly transparent in the useful spectrum of the sunlight and should not absorb wavelengths that are relevant for the solar cell (e.g., 350-1150 nm for crystalline silicon solar cells).

6) Lateral conductivity of the overlaying dielectric: The front overlaying (top) dielectric should be as conductive as possible to ensure good lateral conduction of current. Conductivity may be augmented by adding a transparent conductive oxide (TCO) ITO on top of the front overlaying dielectric.

7) Anti-Reflection coating (ARC): In some cases, the front overlaying dielectric can act as an anti-reflection coating (ARC), removing the need for a separate ARC. Alternatively, an ARC can be added. ITO or a different TCO layer may serve as an ARC as well.

II.B. Back Dielectric Stack Parameters

8) Contact resistance: The back dielectric stack may have a low transportation resistance to holes (carrier selectivity to holes or positive charges), to prevent losing those separated and collected holes to series resistance at the back contact.

9) Electron rejection: The back overlaying dielectric may be a barrier that rejects electrons, very efficiently, to not have loss in Jsc (short current density of the solar cell).

10) Low barrier height between the valence band of the light absorbing layer and the valence band of the overlaying dielectric: This ensures holes may easily tunnel from the light absorbing layer, through the tunneling dielectric, and into the overlaying dielectric. Further, the back dielectric stack materials (and their respective thicknesses) and the metal chosen for the back contact should result in the Fermi level of the back metal contact being close to valence band of the overlaying dielectric and the light absorbing layer. This allows the back side of the solar cell to have a large open-circuit voltage V_{OC} and a good contact resistance. Larger Voc values also result in smaller absolute values for temperature coefficient of power in solar cells which is highly desirable for enhanced energy yield of the solar cell.

11) Transparency: If the solar cell is intended to be bifacial, the dielectric stack materials and back contact should be transparent. If the solar cell is not intended to be bifacial (i.e., for monofacial solar cells), transparency on the backside is not as advantageous or necessary.

12) Conductivity of the back overlaying dielectric/semi-insulator: If the solar cell is intended to be bifacial, the back overlaying dielectric should be as conductive as possible to ensure good lateral conduction of electrical current with minimal parasitic ohmic losses. Conductivity may be augmented by adding a TCO such as ITO on top of the back overlaying dielectric. If the solar cell is not intended to be bifacial (i.e., monofacial solar cells), the conductivity requirement for the back overlaying dielectric may be reduced relative to the bifacial embodiment, as the back contact may be a relatively thin blanket metal layer (i.e., applied over substantially all of the back overlaying dielectric), thus allowing the additional surface area with the contact to mitigate the reduced conductivity of the back overlaying dielectric.

In an alternative embodiment of the solar cell, a multi-level dielectric stack may be such that the layers touching the absorber do not necessarily comprise a tunneling layer but a layer with the band offset which is conducive for charge carrier selectivity.

II.C. Example Front Contact Solar Cell

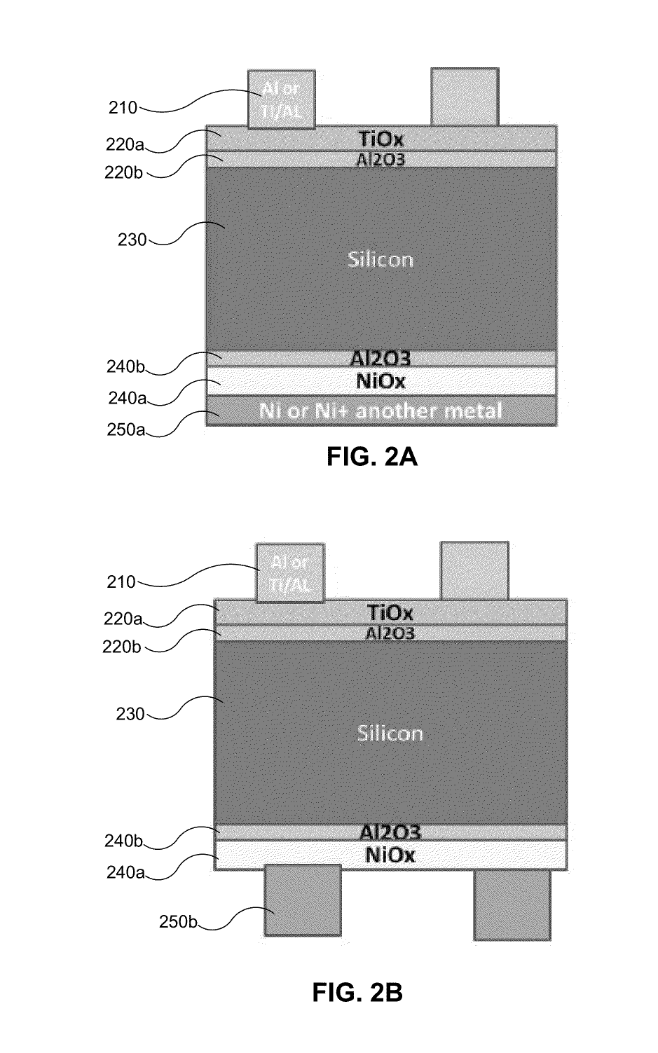

Two example front contact solar cells are shown in FIGS. 2A and 2B. FIG. 2A shows a front contact solar cell including a blanket back contact, according to one embodiment. FIG. 2B shows a bifacial front contact solar cell including a patterned back contact, according to one embodiment.

In the examples of FIGS. 2A and 2B, the light absorbing layer is made of intrinsic or lightly doped (for example: about 1×10¹⁴ dopant atoms/cm³) crystalline silicon. In this example, the solar cells include two layers in the front dielectric stack 220, a tunneling dielectric layer made of aluminum oxide (Al₂O₃) 220b and an overlaying dielectric layer of titanium oxide (TiOₓ) 220a. The front contact 210 is a patterned metal contact on top of the overlaying dielectric, and in this embodiment acts as the base contact by absorbing electrons. The front contact may be made of Al, Ti, or a combination thereof which have work function close to that of the conduction band of crystalline silicon. The solar cells include two layers in the back dielectric stack 240, a tunneling dielectric layer of Al₂O₃ 240b, and an overlaying dielectric layer of NiOₓ 240a. The back contact 250 is either a blanket (FIG. 2A) metal contact 250a, or a patterned (FIG. 2B) metal contact 250b for a bifacial front contact solar cell.

In one specific embodiment of either of these example solar cells, the front Al₂O₃ layer 220b is between about 0 to 2.5 nanometers (nm), the front TiOₓ layer 220a is between about 1 to 40 nm, the back Al₂O₃ layer 240b is between about 0 to 2.5 nm, and the back NiOₓ layer 240a is between about 1 to 10 nm.

Importantly, several other examples of dielectrics may be used to give the aforementioned properties. One particular example includes for the electron selective contact (on the front-side) a combination of a thin SiO₂ (<1.5 nm) and a-Si may be used, where as for the hole selective contact a thin Al₂O₃ with a-Si may be used. Other choices for the sandwiched dielectrics include materials which are known to give good passivation and allow carrier tunneling through them including dielectrics such as HfO₂.

Although not necessary, the example solar cells of FIGS. 2A and 2B may include all of the features 1-13 introduced above. The following two sections describe in further detail how these example solar cells may include these features.

II.C.1 Example Front Contact Properties

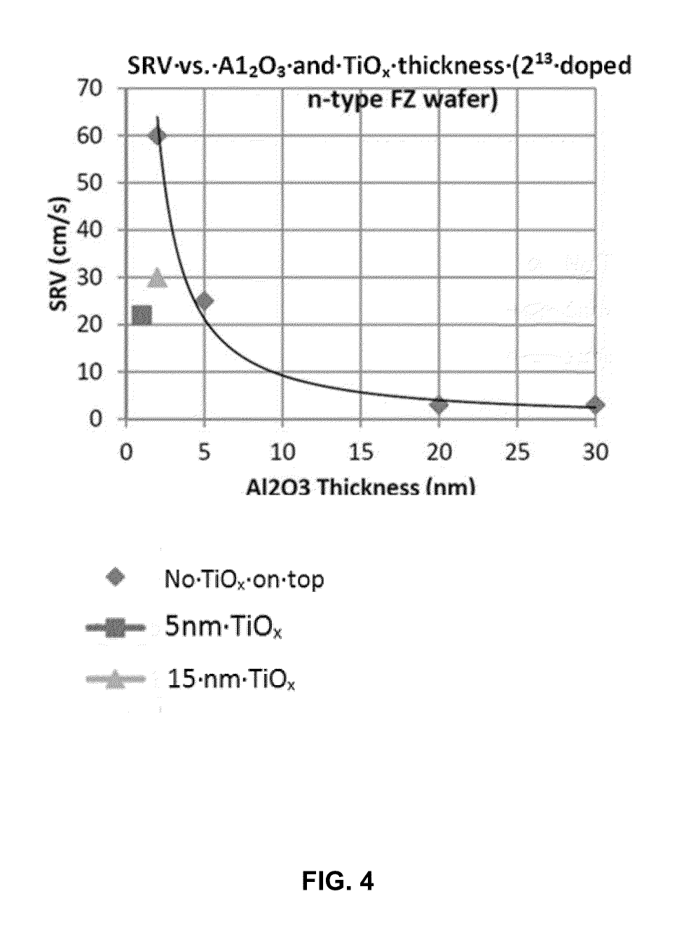

Regarding front side passivation (1), Al₂O₃ by itself is an excellent passivation for n-type doped, p-type doped, and intrinsic (native) semiconductors such as Si. Using Al₂O₃, SRVs less than 10 cm/s may be achieved. Al₂O₃ by itself is a dielectric, and consequently it blocks conduction of electrons. If the Al₂O₃ layer is sufficiently thin (e.g., less than about 2 nm, and in some instances <1 nm thick), it allows electrons to tunnel through. However, at these thicknesses, Al₂O₃ may start to lose its passivation quality. FIG. 4 illustrates this concept, showing SRV as a function of Al₂O₃ thickness, according to one embodiment.

The overlaying dielectrics address this passivation problem for thin layers of Al₂O₃ for both the front and back dielectric stacks. For the front dielectric stack, the overlaying dielectric layer may be TiOₓ. TiOₓ improves Al₂O₃ passivation even for a thin Al₂O₃ (e.g., less than 2 nm thick). FIG. 4 illustrates this concept as well, showing that despite a thin (e.g., 1 nm) layer of Al₂O₃, SRV may still be reduced to approximately 20 cm/s from greater than 60-100 cm/s with 5 nm of TiOₓ as an overlaying dielectric.

As a possible additional benefit, TiOₓ can be made more conductive if made non-stoichiometric and oxygen deficient. For example, TiOₓ resistivity can be made as low as approximately 1×10⁻² Ω-cm by adding a layer of Ti on the TiOₓ (Titanium getters oxygen) or by annealing the TiOₓ/Al₂O₃ stack to a temperature greater than approximately 400° C. in a reducing forming gas annealing (FGA) environment. The oxygen vacancies in TiOₓ serve as dopants to make it more conductive.

Regarding front contact resistance (2), a thin layer of TiOₓ (e.g., 1-2 nm) on top of the Al₂O₃ may significantly improve contact resistance relative to simply having the metal in direct physical contact with the light absorbing layer. For example, in one embodiment either Al or Ti is used as the front contact (or other metals with a vacuum work function close to the conduction band of the light absorbing layer). Al and Ti have vacuum work functions of 4.15 eV and 4.3 eV, respectively. These metals will have a barrier height to TiOₓ of only approximately 0.15 eV, compared to 0.65 eV if they were directly in contact with Si. This may decrease contact resistance substantially. Current may be carried by field assisted tunneling or by field assisted thermionic emission.

Choosing a specific thickness for the TiOₓ layer is an optimization problem for obtaining the lowest contact resistance. The thicker the TiOₓ layer is made, the closer the Fermi level of Al or Ti will be to the charge neutrality level (CNL) (described further below) of TiOₓ which yields more tunneling current as a general principle. However, a thicker TiOₓ may also makes tunneling more difficult. The thickness Al₂O₃ layer is also a factor, which does not affect contact resistance but does require carriers to tunnel through. Thus the combined thickness of TiOₓ and Al₂O₃ may be considered when determining tunneling current. In one embodiment, the TiOₓ thickness is thus chosen to minimize contact resistance for a given solar cell layout.

Regarding front hole rejection (3), both Al₂O₃ and TiOₓ present a high energy barrier height to holes because of the band discontinuity between the respective valence bands of Si, TiOₓ, and Al₂O₃.

Regarding the low barrier height from the conduction band of the overlaying dielectric to the conduction band of the light absorbing layer (4), in an intrinsic semiconductor directly attached to front and back contacts, the V_{OC} may be dictated by the difference in the Fermi level work functions of the front and the back contacts. Hence, to obtain a large V_{OC}, it may be advantageous to have the front contact Fermi level as close to conduction band of the semiconductor and the back metal Fermi level as close to the valence band of the semiconductor as possible.

When a metal is in direct contact with a semiconductor such as crystalline silicon, the metal's work function is pinned to approximately the mid-gap of Si, also known as the charge neutrality level (CNL) because of the presence of surface dipoles. Adding a thin dielectric such as TiOₓ unpins the metal work function from that of CNL of Si to the CNL of the dielectric. TiOₓ has several advantages in this regard: 1) its conduction band is almost aligned with the conduction band of Si, 2) the CNL of TiOₓ is close to conduction band of Si resulting in a very low Schottky barrier to Si, 3) TiOₓ can be made conductive (as introduced above). In one embodiment 2 nm of TiOₓ may be ample to unpin the Fermi level of the Al or Ti contact to the CNL of TiOₓ. Thus, TiOₓ may work well for creating a low barrier height.

Regarding transparency of the front dielectric stack (5), TiOₓ and Al₂O₃ are optically transparent in the wavelengths of interest for silicon light absorbing layers (e.g., 350-1150 nm).

Regarding lateral conductivity of the front overlaying dielectric (6), to create a solar cell with a certain set of properties, a threshold level of conductivity for the front overlaying dielectric is needed. This threshold depends upon the lateral spacing between the lines of the front contact. The more finely patterned the metal lines are, the smaller the lateral spacing of the front contact metal “grid” while still maintaining the same percent coverage of total front surface coverage (and thus light rejection) of the solar cell.

To improve lateral conductivity, the TiOₓ may be made oxygen deficient through addition of Ti or through annealing as introduced above. However, a trade off with adding Ti and making the TiOₓ/Ti layer too thick is that tunneling of charge carriers from Si towards the metal contact may be made more difficult (increased tunneling resistance). Additionally, if the TiOₓ/Ti layer is greater than 40 nm thick, the TiOₓ may no longer act as a good ARC.

Regarding the front ARC (7), approximately 40 nm TiOₓ may serve as an excellent ARC layer. The presence of the thin Al₂O₃ underneath the TiOₓ may not affect the optical ARC properties as its optical thickness is much smaller than the wavelength of the light being absorbed (e.g., 350 nm to 1150 nm). If a thinner TiOₓ layer is desired, the TiOₓ thickness may be reduced below approximately 40 nm and a separate ARC may be added on top of the TiOₓ and metal contact.

In another embodiment, if the TiOx layer is not found to possess enough electrical conductivity, a separate TCO layer such as ITO may be deposited on top of TiOx layer. This will provide lateral conductivity. In this scenario, the ARC properties may be optimized by changing the thickness of TiOx and the TCO combination. For example, one combination may keep the TiOx layer thin and provide about 80 nm of ITO for good lateral conductivity and ARC properties.

II.C.2 Example Back Contact Properties

Regarding back side passivation (8), as described above Al₂O₃ by itself is excellent for passivation on crystalline silicon. NiOₓ and Al₂O₃ may also work well together to improve passivation. The description above for the combined passivation of Al₂O₃ and TiOₓ is similarly applicable to the combined passivation of Al₂O₃ and NiOₓ, with the exception of the thickness for the NiOₓ layer. In one embodiment, passivation is achieved by having a NiOₓ thickness of between approximately 1-10 nm.

Regarding resistance (9), the thin layer of NiOₓ (e.g., approximately 1 to 2 nm) on top of the Al₂O₃ may significantly improves contact resistance relative to simply having the metal in direct physical contact with the light absorbing layer. For example, in one example embodiment Ni is used as the back metal contact (or Ni+, Pt, or another metal with a vacuum work function close Si's valence band). Ni has vacuum work functions of ˜5.1 eV eV. Thus, Ni will have a very small to negligible barrier to NiOₓ. This may decrease contact resistance substantially. Current is carried by field assisted tunneling or by field assisted thermionic emission. Choosing a specific thickness for the NiOx/Al2O3 stack layer is an optimization problem for obtaining the lowest contact resistance and the best passivation, similarly to the case for TiOx/Al2O3 described above.

Regarding back electron rejection (10), both Al₂O₃ and NiOₓ may present a high energy barrier height to electrons because of the band discontinuity between the respective conduction bands of NiOₓ and Si.

Regarding the low barrier height from the valence band of the overlaying dielectric to the valence band of the light absorbing layer (11), as described above, to obtain a large V_{OC} it may be advantageous that the back metal Fermi level is as close to the valence band of the overlaying dielectric as possible. This is the case for NiOₓ. Further, NiOₓ has an excellent property that its valence band lines up approximately with Si's valence band, providing very little barrier to holes. In an embodiment where the back dielectric stack has a prohibitively large SRV, a different material other than NiOₓ may be used which also has a small bandgap to the valence band of Silicon, and a high rejection barrier to electrons.

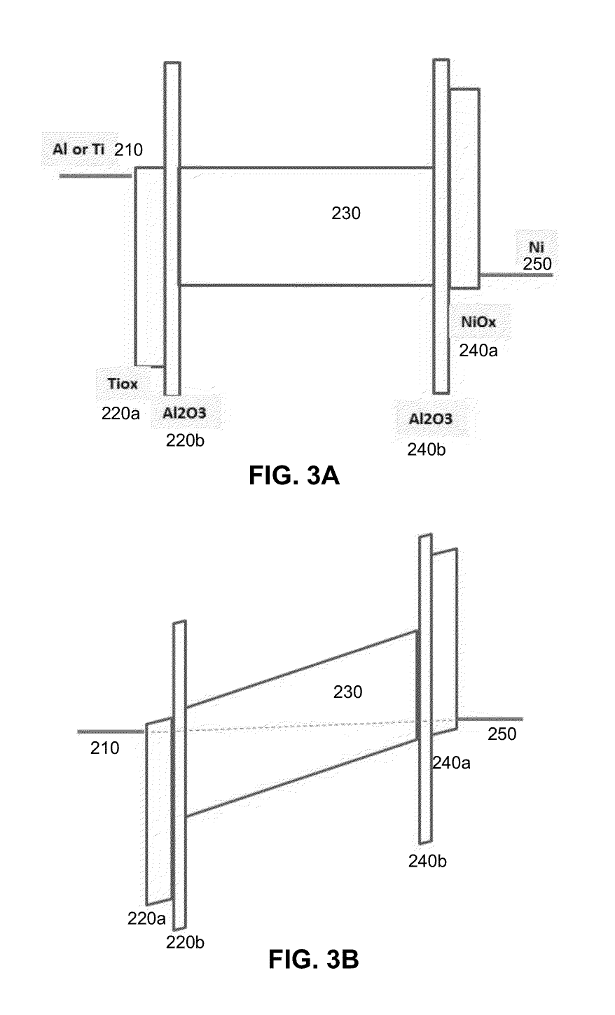

Regarding properties (4) and (11) together, FIGS. 3A and 3B are energy band diagrams for the example front contact solar cell. FIG. 3A shows an energy band diagram of the example front contact solar cell at flat band voltage (open circuit condition), according to one embodiment. FIG. 3B shows an energy band diagram of the example front contact solar cell at zero applied voltage (short circuit condition), according to one embodiment. FIGS. 3A and 3B illustrate how the front dielectric stack may allow electrons to tunnel easily through the Al₂O₃ into the conduction band of the TiOₓ, and then easily transition into the Al or Ti front contact. FIGS. 3A and 3B further illustrate how difficult it may be for holes to make a similar tunneling/transition across to the front contact. FIGS. 3A and 3B further illustrate how the back dielectric stack may allow holes to tunnel easily through the Al₂O₃ into the valence band of the NiOₓ, and then easily transition into the Ni back contact. FIGS. 3 and 3B further illustrate how difficult it may be for electrons to make a similar tunneling/transition across to the front contact.

Regarding transparency of the back dielectric stack (12), NiOₓ and Al₂O₃ are transparent, and this example solar cell is suitable to be used as a bifacial solar cell.

Regarding the lateral electrical conductivity of the back overlaying dielectric (13), as above if the solar cell is not intended to be bifacial (i.e., being a monofacial solar cell), a blanket layer of the back contact (e.g., Ni) provides sufficient conductivity. If a bifacial solar cell is intended, conductivity may be augmented through the addition of a layer of ITO.

II.D. Alternate Embodiments of the Example Front Contact Solar Cell

Although the light absorbing layer (in this example Si) has been described as having little to no doping, in another embodiment the light absorbing layer includes a substantial amount of doping, while still including the same dielectrics stacks and metals on the front and the back of the solar cell as described above. The light absorbing layer can be made n-type or p-type. The process flow for fabricating the solar cell may be the same, but for one or more additional doping steps prior to the addition of the dielectric stacks. However, the solar cell may function somewhat differently because of a lack of the built-in field assisted carrier transport. than with an intrinsic or lightly doped light absorbing layer. Notably, the solar cell will have a different series resistance.

In the same or an alternative embodiment, for an n-type base, the back side of the solar cell may include an ohmic contact and a conventional diffused emitter, making it a rear emitter with passivated front contact solar cell. A localized ohmic contact may be made by adding heavy localized p+ doping (e.g., 1×10²⁰ dopant atoms/cm³) to the semiconductor absorber layer, and by using a suitable metal such as Al to make an emitter contact. In addition, the emitter may be made on the back side by diffusing a light p− doping (e.g., 1×10¹⁹ dopant atoms/cm³) in less than 1 um of the back side of the solar cell. The rear side is still covered with a dielectric passivation which is not restrictive and may be selected be from the myriad options of SiNx or a SiNx/AlO₃ combination. The localized contacts may be made by opening up the dielectric sporadically and locally. In this embodiment, the front dielectric stack and an Al and/or Ti metal contact as described above may still serve as an electron collector (base).

In another embodiment analogous to the previous embodiment, the base stack consisting of either the Al2O3/TIOx or the SiO2/a-Si may be replaced by a conventional base with n+ doping (for an n-type silicon) local contacts while the emitter stack still includes the structure described above (AL2O3/NiOx or Al2O3/A-Si). Thus both possibilities of having emitter on the front or on the back exists. And the transparency should be ensured on the front side for either configuration.

### III. Front Contact Solar Cell Fabrication with a Wafer

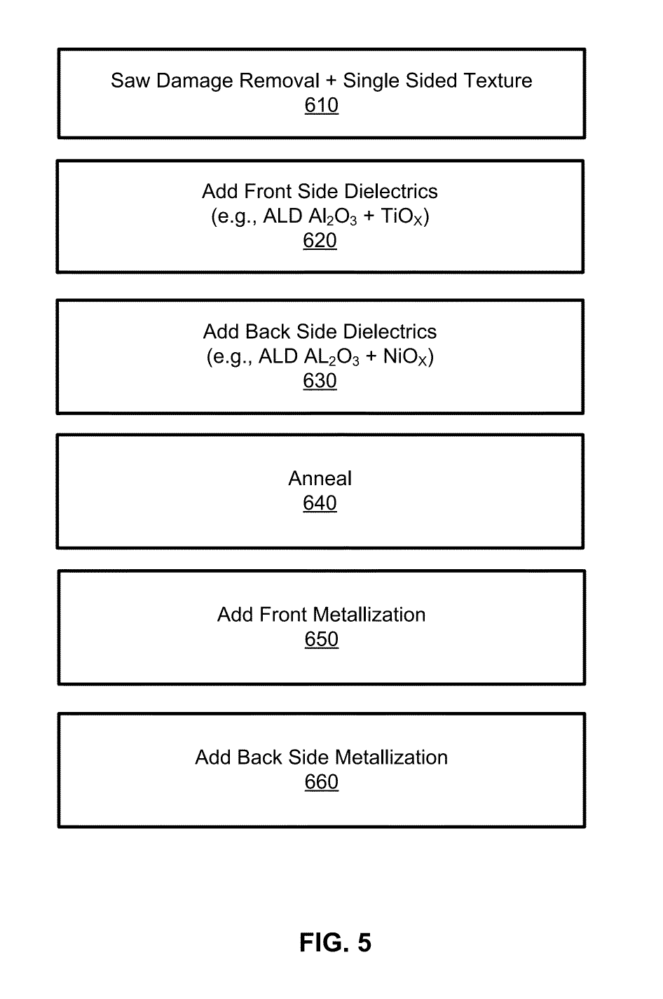

FIG. 5 illustrates a basic process for manufacturing a front contact solar cell starting with a wafer, according to one embodiment. The fabrication process shown in FIG=. 6 focusses on an embodiment where the base stack is made of Al2O3/TiOx and emitter stack is with Al2O3/NiOx and should be interpreted only as a representative example and thus not a structure limitation. References to other structures may also be made when appropriate. In the example of FIG. 5, the starting point for the light absorbing layer is a wafer of material, such as mono-crystalline Si (e.g., Czocharalski (CZ) Si) or multi-crystalline Si (mc-Si). The dopant type of the Si may vary (e.g., n-type or p-type, or near intrinsic crystalline silicon

Saw damage removal (SDR) is performed 610 with standard wet chemistry and a single sided texture with standard alkaline texturing chemistry on the sunny side (the light receiving side of the solar cell). The SDR 610 reduces the wafer thickness to approximately the desired silicon thickness and removes any saw damage to give a good bulk minority carrier lifetime. Other techniques for reducing wafer thickness may also be used, such as mechanical surface grinding, chemical silicon etching, cleaving using proton implantation, laser splitting, or stress induced cleaving. The wafer is then cleaned, removing any leftover cutting slurry on the surface wafer as well as the top few μm of the wafer.

Two different layers of dielectric are added 620 on the front side (sunny side) of the light absorbing layer to form the front dielectric stack. The first layer added is the tunneling dielectric, for example Al₂O₃. The second layer added is the overlaying dielectric, for example TiOₓ. These layers may be added 620 using a variety of techniques. For example, Atomic layer deposition (ALD) may be used where high volume solar-grade reactors are available. Plasma ALD or Plasma Enhanced Chemical vapor deposition (PECVD) may also be used. In other embodiments, where the front dielectric stack includes more than two layers, these additional layers may be added in order from closest to farthest from the light absorbing layer.

Two different layers of material are added 630 on the back side (non-sunny side) of the light absorbing layer to form the back dielectric stack. Similarly to the first front layer, the first back layer is a tunneling dielectric, for example Al₂O₃. The first back layer may generally be made of the same material as is used for the first front layer, but this is not strictly necessary. As introduced above, the second back layer is an overlaying dielectric made of a different material than the second front layer, for example NiOₓ. The same techniques used to add 620 the front layers may also be used to add 630 the back layers.

As an alternative example of a structure set, the front layers (base for n-type silicon) may be thermally grown SiO2 (for instance, <1.5 nm thickness using short dry oxidation) and deposited PECVD a-Si, while the backside dielectric stack may Al2O3+PECVD a-Si. For example, this structure may be formed as follows: single sided thermal oxide growth using back to back wafers or removing oxide from the non-sunny side of the wafer followed by Al2O3 deposition and PECVD a-Si deposition on both sides.

The light absorbing layer and attached front and back dielectric stacks may be annealed 640 to ensure that the passivation of the first films is activated and is of good quality. In one implementation, the anneal is performed at approximately 400° C. in a reducing forming gas for approximately 10 to 30 minutes, although other ambient gasses such as N₂ may also be used Depending upon the materials used in the overlaying dielectrics, the anneal may also have the effect of increasing the conductivity of one or both of the second films. For example, if the second front film is made of TiOₓ, the anneal may cause the TiOₓ to become deficient in oxygen, thus increasing its conductivity, particularly if performed in a reducing forming gas environment.

Front and back electrical contacts are added 650, 660 onto the front and back films, respectively. The material used in for the contacts may vary, examples include metals such as Al, Ti, Ti followed by Al, Cu, Ag, Ni, or another suitable metal. The contacts may also be made of other conductive materials such as ITO. The front and back metal contacts are made of different materials, in order to be more compatible with the conduction or valence bands of the overlaying dielectrics as described above. For example, if the front overlaying dielectric is made of TiOₓ, the front contact may also be made of Ti, or Ti followed by another metal. Similarly, if the back overlaying dielectric is made of NiOₓ, the back contact may be made of Ni, or Ni followed by another metal.

The contacts may be added using a variety of techniques, including screen printing a non-fitted low-cure-temperature paste, inkjet printing, sputtering/evaporating a blank layer of material followed by subsequent patterning, PVD deposition in some cases followed by patterning. If the solar cell is going to be a bifacial solar cell (i.e., incident light is harvested on both the front and back sides), Ni can also be ink jetted onto the front and back films followed by another metal to thicken the contacts and lower resistivity.

In the case where the lateral conductivity of one of the second films is not sufficient (e.g., in some cases where TiOₓ is used as the second film), Indium Tin Oxide (ITO) may be sputtered on top of the second film either before or after the anneal step. The ITO is electrically conductive and thus increases conductivity, and is also transparent and thus does not significantly impact the yield of the solar cell.

An anti-reflection coating (ARC) may also be added on the front and back sides of the solar cell. The ARC may be made of a material such as SiN.

In a non-bifacial implementation where the lateral conductivity of the back contact is initially insufficiently high, additional layers and process steps may be added to improve its lateral conductivity. For example, a dielectric backplane sheet (e.g., aramid fiber and resin) may be laminated onto the back side contact, and then a second layer metallization (e.g., a sheet of material such as Al foil) may be added onto the backplane sheet. The back contact and second layer metallization may be electrically connected through vias in the backplane sheet. Alternatively, a conductive backplane sheet may be laminated onto the back contact. Anneal step 640 may be performed before, after, or both before and after the addition of the backplane sheet and/or the second layer metallization.

In another version of this process, anneal step 640 may instead be performed after the metallization 650, 660 (or after any subsequent metallization process) instead of before metallization 650,660. This may be advantageous if, for example, the anneal reduces the electrical resistance between the metal contacts added in steps 650 and 660 and any subsequent metallization process or other components of the solar cell, and/or between the metal contacts and the dielectric stacks.

### IV. Front Contact Solar Cell Using an Epitaxially Grown Light Absorber

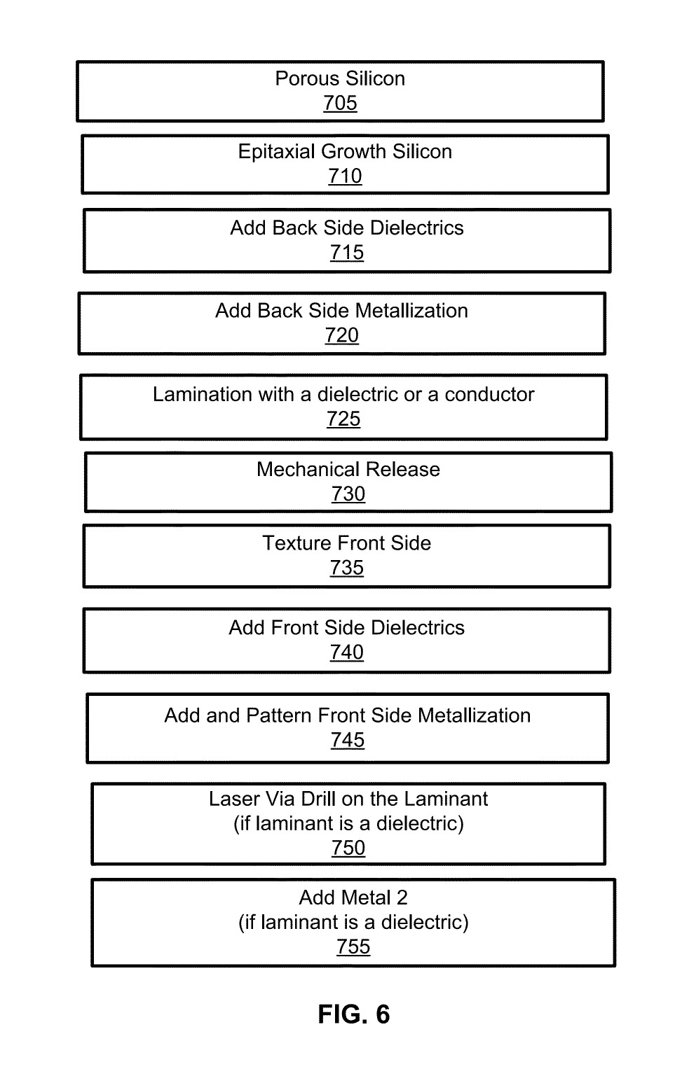

FIG. 6 illustrates a process for fabricating a front contact solar cell where the light absorbing layer is epitaxially grown, according to one embodiment. In the example of FIG. 6, the light absorbing layer is grown with a reusable silicon template such as a crystalline semiconductor wafer with porous semiconductor layer on its surface 705, examples of which include CZ Si, mc-Si, or another semiconductor. Porous semiconductor (such as porous silicon on crystalline silicon wafer) is used as an epitaxial seed layer and a lift-off release layer. If the wafer has been used previously to grow another light absorbing layer, it is reconditioned and cleaned prior to its reuse to produce additional semiconductor layers for solar cells using epitaxial growth on porous semiconductor layer formed on the semiconductor wafer.

A porous silicon epitaxial seed and release layer is formed 710 on the surface of the crystalline silicon wafer. In one example, the seed and release layer are different layers having different porosities. The seed layer on which the silicon will be grown may have a relatively low porosity which favors growth of low-defectivity silicon. The release layer in contact with the template may have a relatively high porosity, facilitating on-demand lift-off separation once growth of the silicon is complete. A thin layer of epitaxial silicon is then grown or chemical-vapor deposited on the outer of the layers. This epitaxially grown layer becomes the light absorbing layer. In one implementation, the grown layer of epitaxial silicon is typically between approximately 1 μm and 80 μm thick.

Once the light absorbing layer has been grown 710, the exposed surface of the light absorbing layer not facing the template is the back side of the light absorbing layer. Prior to releasing the light absorbing layer from the template, the back side of solar cell may be processed. Processing of the back side of the solar cell includes adding 715 two or more layers of materials to form the back dielectric stack, similarly to step 630 described above. A back metal contact is added 720 on the back dielectric stack, similarly to step 660 described above. Depending upon the implementation, a conductive or dielectric backplane sheet may be laminated 725 on the back contact (e.g., a prepreg sheet). Although not illustrated in FIG. 5, the addition of the backplane sheet is the same step as introduced in the section described FIG. 5 above.

The solar cell is separated 730 from the template using a mechanical release serving as lift off separation process releasing the solar cell along the porous layer (or alternatively a wet chemical etch release releasing the solar cell along the porous layer). Processing may then begin on the front side of the solar cell. Processing of the front side may include texturing 735 the front side of the light absorbing layer using standard alkaline chemistries involving potassium hydroxide or sodium hydroxide. The backplane (such as a thin prepreg sheet) may be chemically resistant and compatible with the wet texture chemistries.

Two or more layers of materials are added 735 to form the front dielectric stack, similarly to step 620 described above. Like the wafer implementation, the overlaying dielectric added on the front side of the light absorbing layer is different from the overlaying dielectric added on the back side of the light absorbing layer.

The front contact is added 745, similarly to step 650 described above.

Additional steps may also be performed depending upon the materials used in the other steps. If a dielectric backplane sheet was laminated 725 on the back contact, the backplane sheet is drilled 750 to create vias accessing the back contact underneath the backplane sheet. A second layer metallization may be added 755 on the backplane sheet and interconnected with the back contact. If the backplane sheet is made of a conductive material, steps 750 and 755 may be skipped.

Although not shown in FIG. 6, one or more anneals may also be performed in between any of the steps mentioned above Anneals may cause a variety of effects, such as activating passivation layers, creating stronger electrical connections, and other benefits.

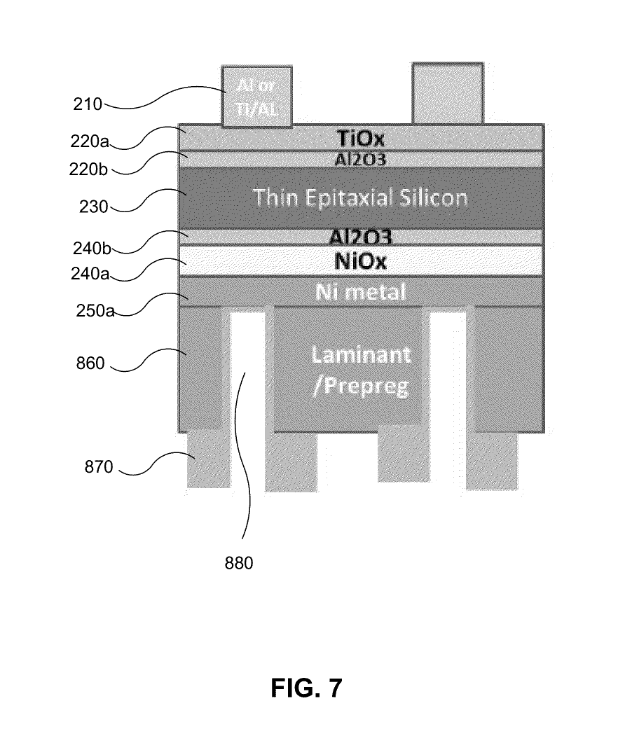

FIG. 7 illustrates one possible example of a solar cell created using an epitaxially grown solar cell that also include a dielectric backplane sheet 860 (such as a laminant/prepreg sheet) and a second layer metallization 870 interconnecting with the back metal contact 250a (e.g., Ni or Ni plus another metal) through vias 880, according to one possible example of the process illustrated in FIG. 6. Although not shown, the front surface may be textured and may have an ARC coating.

In another embodiment, a back contact solar cell may be made using similar concepts as demonstrated above. In the specific embodiment involving a base dielectric stack Al2O3/TiOx and emitter stack Al2O3/NiOx, a common dielectric layer of Al2O3 may be deposited using a myriad techniques (such as PECVD, ALD, APCVD etc). Thickness control and uniformity is important making ALD a suitable choice. This is followed by a patterned NiOx/Ni stack alternating with a patterned TiOx/Ti (or AL) in an interdigitated fashion to completed a back contacted solar cell.

### IV. Additional Considerations

Upon reading this disclosure, those of skill in the art will appreciate still additional alternative structural and functional designs through the disclosed principles herein. Thus, while particular embodiments and applications have been illustrated and described, it is to be understood that the disclosed embodiments are not limited to the precise construction and components disclosed herein. Various modifications, changes and variations, which will be apparent to those skilled in the art, may be made in the arrangement, operation and details of the method and apparatus disclosed herein without departing from the spirit and scope defined in the appended claims.

What is claimed is:

1. A photovoltaic solar cell comprising:
a semiconductor light absorbing layer;
a dielectric stack on either a front side of the light absorbing layer or a back side of the light absorbing layer, the dielectric stack comprising:
a tunneling dielectric layer physically contacting the light absorbing layer, the tunneling dielectric being sufficiently thin for charge carriers to tunnel across;
an overlaying dielectric layer physically contacting the tunneling dielectric layer, the tunneling dielectric being a different material than the overlaying dielectric; and
an electrically conductive contact physically contacting the overlaying dielectric, the electrically conductive contact and the overlaying dielectric together having either:
a work function suitable for selective collection of electrons that closely matches a conduction band of the light absorbing layer, or
a work function suitable for selective collection of holes that closely matches a valence band of the light absorbing layer.

2. The photovoltaic solar cell of claim 1,
wherein the dielectric stack is a front dielectric stack on the light-receiving front side of the light absorbing layer;
wherein the overlaying dielectric of the front dielectric stack and the conductive contact comprise the work function for electrons that closely matches the conduction band of the light absorbing layer; and
wherein the photovoltaic solar cell further comprises:
a back dielectric stack on the back side of the light absorbing layer, the back dielectric stack comprising a plurality of layers of dielectric materials; and
a back conductive contact physically contacting the back dielectric stack, the back conductive contact and the back dielectric stack together having the work function suitable for holes that closely matches the valence band of the light absorbing layer.

3. The solar cell of claim 2, wherein the back dielectric stack comprises:
a back tunneling dielectric layer physically contacting the light absorbing layer, the back tunneling dielectric being sufficiently thin for charge carriers to tunnel across; and
a back overlaying dielectric layer physically contacting the back tunneling dielectric layer, the back tunneling dielectric being a different material than the back overlaying dielectric and the front tunneling dielectric.

4. The photovoltaic solar cell of claim 1,
wherein a side of the light absorbing layer opposite the side attached to the dielectric stack comprises a doped region; and
wherein the photovoltaic solar cell further comprises a second conductive contact attached to the doped side of the light absorbing layer, the doped side of the light absorbing layer and the second conductive contact forming an ohmic contact.

5. The photovoltaic solar cell of claim 4, wherein the doping is a p+ doping, and the second conductive contact is a metal such as Aluminum, Titanium, or an alloy thereof.

6. The photovoltaic solar cell of claim 4, wherein the doping is a n− doping, and the second conductive contact is a metal such as Aluminum, Titanium, or an alloy thereof.

7. The photovoltaic solar cell of claim 1, wherein the tunneling dielectric is made of Al₂O₃.

8. The photovoltaic solar cell of claim 7, wherein the tunneling dielectric is between approximately 0 and 2.5 nanometers (nm) thick.

9. The photovoltaic solar cell of claim 1, wherein the overlaying dielectric is made of TiOₓ.

10. The photovoltaic solar cell of claim 9, wherein the overlaying dielectric is between approximately 1 and 40 nm thick.

11. The photovoltaic solar cell of claim 9, wherein the conductive contact comprises at least one of Titanium and Aluminum metal.

12. The photovoltaic solar cell of claim 1, wherein the overlaying dielectric is made of NiOₓ.

13. The photovoltaic solar cell of claim 12, wherein the overlaying dielectric is between about 1 and 10 nm thick.

14. The photovoltaic solar cell of claim 12, wherein the conductive contact comprises at least one of Nickel (Ni), or Platinum (Pt).

15. The photovoltaic solar cell of claim 1, wherein the light absorbing layer is at least one from the group consisting of an intrinsic semiconductor and a doped semiconductor a doping of charge carriers of a density of no more than approximately 1×10¹⁵ dopant atoms/cm³.

16. The photovoltaic solar cell of claim 1, wherein the tunneling dielectric layer is transparent at least in the wavelength range of approximately 350 to 1150 nm.

17. The photovoltaic solar cell of claim 1, wherein the overlaying dielectric layer is transparent at least in the wavelength range of approximately 350 to 1150 nm.

18. The photovoltaic solar cell of claim 1, further comprising a transparent conductive layer between the overlaying dielectric layer and the conductive contact.

19. The photovoltaic solar cell of claim 1, wherein the transparent conductive layer is Indium Tin Oxide (ITO).

20. The photovoltaic solar cell of claim 1, wherein the conductive contact is patterned to cover only a portion of the overlaying dielectric.

21. The photovoltaic solar cell of claim 1, wherein the conductive contact covers a majority of the overlaying dielectric.

22. The photovoltaic solar cell of claim 1, further comprising an electrically conductive backplane attached to the conductive contact.

23. The photovoltaic solar cell of claim 1, further comprising:
a dielectric backplane attached to the conductive contact, the dielectric backplane comprising a plurality of via holes; and
a second layer conductive contact attached to the dielectric backplane and electrically connected to the conductive contact through the vias.

24. The photovoltaic solar cell of claim 1, wherein the second layer contact is a sheet of Aluminum foil.

25. A method for fabricating a front contact photovoltaic solar cell comprising:
preparing a semiconductor light absorbing layer;
adding a front tunneling dielectric layer physically contacting the light absorbing layer;
adding a front overlaying dielectric layer physically contacting the front tunneling dielectric layer, the front tunneling dielectric being a different material than the front overlaying dielectric;
adding a back tunneling dielectric layer physically contacting the light absorbing layer, the back tunneling dielectric;
adding a back overlaying dielectric layer physically contacting the back tunneling dielectric layer, the back tunneling dielectric being a different material than the back overlaying dielectric; and
adding a front electrically conductive contact physically contacting the front overlaying dielectric, the front conductive contact and the front overlaying dielectric together having a work function suitable for selective collection of electrons that closely matches a conduction band of the light absorbing layer;
adding a back conductive contact physically contacting the back overlaying dielectric, the back conductive contact and the back overlaying dielectric together having a work function suitable for selective collection of holes that closely matches a valence band of the light absorbing layer.

26. A photovoltaic solar cell comprising:
a semiconductor light absorbing layer;
a front tunneling dielectric layer physically contacting the light absorbing layer;
a front overlaying dielectric layer physically contacting the front tunneling dielectric layer, the front tunneling dielectric being a different material than the front overlaying dielectric;
a front electrically conductive contact physically contacting the front overlaying dielectric, the front electrically conductive contact and the front overlaying dielectric together having a work function suitable for selective collection of electrons that closely matches a conduction band of the light absorbing layer;
a back tunneling dielectric layer physically contacting the light absorbing layer;
a back overlaying dielectric layer physically contacting the back tunneling dielectric layer, the back overlaying dielectric being a different material than the back tunneling dielectric and the front overlaying dielectric; and
a back electrically conductive contact physically contacting the back overlaying dielectric, the back electrically conductive contact and the back overlaying dielectric together having a work function suitable for selective collection of holes that closely matches a valence band of the light absorbing layer.

27. A photovoltaic solar cell comprising:
a layer of crystalline silicon;
a front layer of Al₂O₃ physically contacting a front side of the crystalline silicon layer;
a layer of TiOₓ physically contacting the front layer of Al₂O₃;
a front metal contact physically contacting the TiOₓ layer, the front metal contact comprising Aluminum, Titanium, or a combination thereof;
a back layer of Al₂O₃ physically contacting a back side of the crystalline silicon layer;
a layer of NiOₓ physically contacting the back layer of Al₂O₃; and
a back metal contact physically contacting the NiOₓ layer, the back metal contact comprising Nickel, Platinum, or a combination thereof.
